(19) United States
(12) Patent Application Publication
(10) Pub. No.: US 2026/0043838 A1
(43) Pub. Date: Feb. 12, 2026

(54) SYSTEM AND METHOD FOR TESTING A DEVICE ON PRODUCTION LINE

(71) Applicant: PITPATPET LTD, Cambridge (GB)

(72) Inventors: Matthew STORKEY, Cambridge (GB); Andrew NOWELL, Cambridge (GB); Jake APSEY, Cambridge (GB)

(73) Assignee: PITPATPET LTD, Cambridge (GB)

(21) Appl. No.: 18/998,704

(22) PCT Filed: Jul. 26, 2023
(86) PCT No.: PCT/IB2023/057572

§ 371 Date: Jan. 27, 2025

(30) Foreign Application Priority Data
Jul. 26, 2022 (GB) 2210912.8

(51) Int. Cl. G01R 31/01

(52) U.S. Cl. CPC G01R 31/01

(57) ABSTRACT

A system for performing functional testing of a device (102) on a production line. The system includes a self-testing protocol configured to conduct a functionality test on a plurality of components in the device and generate a test data that corresponds to a result of the functionality test; one or more Light Emitting Diodes or other light emitting means configured to generate an encoded signal corresponding to the generated test data, and provide a user interface for indicating one or more states of the device to an end user; and a reader configured to read and decode the encoded signal to provide a functional test analysis for the device. Disclosed also is a method for performing functional testing of a device on a production line.

### TECHNICAL FIELD

This invention relates to production line manufacturing. In particular, though not exclusively, this invention relates to a system and a method for performing functional testing of a device on a production line.

### BACKGROUND

Generally, during the production stage of various devices and appliances, a number of functional or quality tests are carried out in order to check if the devices and appliances are functioning properly or not. Such testing of the devices and appliances is essential before the items are dispatched for sale.

Typically, to perform such tests, the devices and appliances are equipped with some testing protocols that can carry out functionality tests for various components in the devices and appliances. However, oftentimes a lot of these components are concealed within the devices and appliances itself or the devices are sealed. Thus, it becomes difficult to perform testing on such concealed components or a concealed device overall. Moreover, in some scenarios, the components may not have any electrical connection or radio communication to transmit the result of the functionality tests.

Therefore, in light of the foregoing discussion, there exists a need to overcome the aforementioned drawbacks associated with performing functional testing of a device on a production line.

### SUMMARY

A first aspect of the invention provides a system for performing functional testing of a device on a production line, wherein the system comprises:
a self-testing protocol configured to conduct a functionality test on a plurality of components in the device and generate a test data that corresponds to a result of the functionality test;
one or more Light Emitting Diodes configured to
   generate an encoded signal corresponding to the generated test data, and
   provide a user interface for indicating one or more states of the device to an end user; and
a reader configured to read and decode the encoded signal to provide a functional test analysis for the device.

Suitably, the aforementioned system of the present disclosure aims to perform functional self-testing of a device on a production line in such a way that allows a personnel on the production line to easily detect any faults in the device during the production of the device itself.

Herein, the term “device” refers to a machinery that is configured to perform a specific set of functions. Optionally, the device may be mechanical devices, electrical, or electronic devices. Some examples of the device may be a mobile phone, a laptop, a wearable smart device, a refrigerator, an air conditioner etc. Moreover, the system of the present disclosure serves the purpose of performing functional testing of the device on the production line, i.e. while the device is being manufactured or after the assembling of the device yet before the device is packed to be dispatched.

Herein, the term “self-testing protocol” refers to a protocol (or an algorithm) executed by an arrangement of components that are required to run the functional testing and provide results and feedback based on the functional testing of the device. Optionally, the self-testing protocol may be executed using self-testing integrated circuits. Herein, the self-testing protocol is capable of conducting self-tests, i.e., an ability to conduct testing without any external help. Moreover, there are a plurality of components that are installed in the device, where each of the plurality of components installed serves a specific purpose in the device. In this regard, the self-testing integrated circuit may be connected to the plurality of components installed in the device.

Moreover, the self-testing protocol is configured to conduct the functionality test of the plurality of components and generate the test data that corresponds to the result of the functionality test. Herein, the term “functionality test” collectively refers to the self-tests that are conducted by the self-testing integrated circuit for testing the functionality of the plurality of components installed in the device, where the functionality test will generate a result regarding the functionality of the plurality of the components termed as the “test data”. Optionally, the result of the test data may be in the form of ‘Yes’ or ‘No’ statements. Alternatively, the test data may comprise numerical- or percentage-based data.

Optionally, the functional test analysis comprises: an identity of the device, indication of functionality pass or failure of the device, nature of failure of the device, threshold of pass or failure for the device, component missing or mismatch in the device. Herein, the identity of the device may include an identity code or number that authenticates the device, the indication of functionality pass or failure of the device may indicate if the device passes or fails the conducted functionality test, the nature of failure of the device may include a kind of failure in the device, the threshold of pass or failure for the device may include an extent or how serious the failure is, the component missing may include details of a component missing from the device or not functioning as desired, the mismatch in the device may include if any another component is present in the device in place of a correct component. Thus, the functional test analysis contains a detailed analysis report that categorically checks the functionality of the device against various parameters.

The system comprises one or more Light Emitting Diodes or other light emitting means configured to generate an encoded signal corresponding to the generated test data, and provide a user interface for indicating one or more states of the device to an end user. Herein, typically, the one or more Light Emitting Diodes or other light emitting means are activated when an electric current is passed through them, and in response the electrical energy is converted into visible light thereby.

Moreover, for the generated test data of the plurality of components, the one or more Light Emitting Diodes (LEDs) or other light emitting means generate the encoded signal. Herein, the term “encoded signal” refers to a readable pattern of light signals emitted by the one or more LEDs or other light emitting means that contains data corresponding to generated test data in an encoded manner. In this regard, the one or more LEDs or other light emitting means that are used to generate the encoded signal are already pre-installed in the device, thus ensuring that no extra components or hardware are to be installed in the device, hence, making the system cost efficient. Moreover, the encoded signal will be having a mark space ratio independent of the generated test data that is to be sent, i.e. the content of the generated test data will not change the appearance of illumination of the one or more LEDs or other light emitting means, thus making the one or more LEDs or other light emitting means appear at a constant apparent brightness to an end user.

Moreover, the one or more Light Emitting Diodes or other light emitting means are configured to provide a user interface for indicating one or more states of the device to an end user. In this regard, the one or more LEDs or other light emitting means that are pre-installed in the device may be configured to perform a primary function of providing the user interface to an end user of the device or be used for any other user interaction.

Optionally, the one or more Light Emitting Diodes or other light emitting means, selected from at least one of: Organic Light Emitting Diodes, Light Emitting Polymers, Electro-Luminescent Panels, Laser Diodes, Quantum Dot Displays, Incandescent Lamps and Fluorescent Lamps, are configured to indicate the one or more states of the device selected from: a charging status or a working mode of the device or other user interface function. Typically, the Light Emitting Diodes (LEDs) are semiconductor devices that are energy efficient, have a long lifespan, compact size, and rapid response time, and emit light when an electric current is passed through them (convert electrical energy into visible light). Therefore, in the present disclosure, the LEDs serve as indicators of the device's functionality without requiring much space or frequent replacements. Beneficially, the LEDs are available in various colors, including white, red, green, blue, etc., and therefore, herein, LEDs may be combined in different color combinations to uniquely indicate different states of the device.

Optionally, the one or more light emitting means is selected from at least one of: Organic Light Emitting Diodes, Light Emitting Polymers, Electro-Luminescent Panels, Laser Diodes, Quantum Dot Displays, Incandescent Lamps and Fluorescent Lamps. The Organic Light Emitting Diodes (OLEDs) and the Light Emitting Polymers (LEPs) respectively use organic compounds and polymers, instead of inorganic semiconductor materials as used in LED, as an emissive material, and can emit light when an electric current is applied thereto. Similarly, the Electro-Luminescent (EL) Panels emit light when an electric field is applied to them. The Laser Diodes are semiconductor devices that emit coherent light (laser light) when electrically biased. The Plasma Display Panels (PDPs) use ionized gas (plasma) to emit light and create images.

The Incandescent Lamps emit light by heating a wire filament to a high temperature until it glows. The Fluorescent Lamps emit light when electricity excites mercury vapor and causes phosphor coating inside the lamp to fluoresce. The Quantum Dot Displays use quantum dots, which are semiconductor nanocrystals. Similar to the LEDs, the aforementioned one or more light emitting means may be employed in different combinations with varying activation patterns to serve as indicators of the device's functionality.

Herein, the user interface, pre-installed with the one or more Light Emitting Diodes or other light emitting means, may be used to display the charging status of the device i.e., an amount of energy left in the device to the end user of the device. Moreover, the user interface may be used to display the working mode of the device to the end user of the device, i.e., the device might have the ability to work in more than one mode and displays the working mode in which the device is currently working to the end user. Optionally, the working mode may comprise information corresponding to a booting of the device, such as an active mode, a sleep mode, an inactive mode, etc.; a network connection state of the device, such as a connected state, a disconnected state, a connecting state, a limited connectivity state, a no signal state, an airplane mode, etc.; and a pairing state of the device, such as a pairing mode ON state, a pairing mode OFF state, a discovering device state, a pairing initiation state, a pairing confirmation state, etc. Additionally, the one or more Light Emitting Diodes (LED's) or other light emitting means is configured to provide a user interface for indicating other information, such as error or warning indicators, notifications, audio levels, time, date, temperature or environmental conditions, etc.

Moreover, the one or more Light Emitting Diodes or other light emitting means is configured to provide a user interface for indicating a pass or failure of the device. In this regard, the one or more Light Emitting Diodes or other light emitting means may be activated in a defined manner to indicate a functionality pass or failure of the device, a threshold of pass or failure for the device, a nature of failure of the device, etc. Specifically, information relating to the device on the production line is relayed over a rapidly changing digital signal encoded in the one or more Light Emitting Diodes or other light emitting means pulses.

Optionally, the encoded signal is generated in accordance with an encoding scheme. Herein, the term “encoding scheme” refers to a way of representing binary bits of the generated test data, that is used by the one or more LED's to generate the corresponding encoded signal. Herein, the use of encoding scheme to represent the generated test data allows to remove any redundancies from the generated test data and thus reduces a final size of the generated test data.

Optionally, the encoding scheme is selected from at least one of: a Manchester line coding, a return to zero (RZ) line coding, a non return to zero (NRZ) line coding. Herein, the Manchester line coding, the return to zero (RZ) line coding and the non-return to zero (NRZ) line coding are different ways of representing the binary bits of the generated test data that may be used by the one or more LED's for generating the corresponding encoded signal. In this regard, the Manchester line coding encodes each data as either low then high or high then low, for equal time, to control phase of a square wave carrier. Notably, the Manchester line coding may have a transition in the middle or at the start of each bit period. The return to zero (RZ) line coding is a binary coding wherein signal drops to 0 between each pulse (typically mid-way of each bit), wherein zero is the neutral or rest condition between the significant binary coding representing 1 bit and 0 bit. Notably, the RZ line coding always begins and ends at 0. The non return to zero (NRZ) line coding is a binary coding wherein the 1's depict a positive voltage and the 0's depict a negative voltage or neutral state, for example. Notably, the NRZ line coding may or may not begin and end at 0, it may also have 0's in the middle. Moreover, NRZ line coding has more energy than the RZ line coding but requires a lower bandwidth compared to the RZ line coding and the Manchester line coding. It will be appreciated that there may be other serial data encoding schemes known to a person skilled in the art that could also be used.

It is to be noted that by using Manchester encoding or any other coding scheme where the mark space ratio (average of the ones and zeros) of the data is independent of the data been sent, the content of the data will not change the visual state of the LEDs and they will appear as constant apparent brightness. In other words, the data rate that is used is faster than is perceived by human eye.

Therefore, the test information can be communicated using the same set of LED(s) that is also used for providing visual indication to an end user of the device. Advantageously, this saves cost and space as no extra hardware is needed in the device to implement this feature.

Optionally, the encoded signal is implemented as a lighting pattern corresponding to electrical signals of a single wire serial interface. Typically, the single wire serial interface requires only a single conductor (a physical wire) for bidirectional data transmission, such as via electrical signals) between two or more devices. In this regard, the electrical signals represent the binary data being transmitted to allow reliable communication using a single wire for both data transmission and reception. In essence, the bits of the generated test data that are represented by the encoding scheme are used in a serial manner of one bit after the other bit for generating the corresponding encoded signal which is in the form of a lighting pattern. The electrical signal, which contains the data to be transmitted, modulates the intensity of the light emitted by the one or more LEDs or other light emitting means. Modulation is achieved by varying the current applied to the one or more LEDs or other light emitting means in proportion to the binary data being transmitted. As the current changes, the intensity of the light also changes. Thus, the use of single wire serial interface ensures cost-effective installation of the system as only a single wire is required for the purpose of generating the encoded signal according to the encoding scheme.

Furthermore, the term “reader” refers to a component that is capable of reading the encoded signal that is generated by the one or more LED's and based on the reading of the encoded signal by the reader, the reader decodes the encoded signal. Subsequently, based on the results achieved via the decoding of the encoded signal, the reader provides the functional test analysis for the device to a production line worker that is responsible for verifying the functionality of the device. Herein, the term “functional test analysis” refers to a report that contains the results and analysis of the functionality test conducted on the plurality of components in the device. Herein, the functional test analysis helps the worker, namely, a production line worker, to correctly authenticate if the device is efficiently working or not. Optionally, the reader is installed in the system as separately from the device, preferably in the production line, thus enabling the reader to read and decode the encoded signal coming out of the device via the one or more LED's.

Optionally, the system further comprises a storage database configured to store the test data and the functionality test analysis. Herein, the storage database may be a cloud-based database or an external device that stores the test data and functionality test analysis for the purpose of future reference or to run a detailed analysis on the stored test data and the functionality test analysis for generating further inferences.

Thus, the system may compare the functional test analysis of the devices manufactured in two or more separate batches.

A second aspect of the invention provides a method for performing functional testing of a device on a production line, wherein the method comprising:
conducting a functionality test on a plurality of components in the device and generating a test data that corresponds to a result of the functionality test;
generating an encoded signal corresponding to the generated test data;
indicating one or more states of the device to an end user; and
reading and decoding the encoded signal to provide a functional test analysis for the device.

Various embodiments and variants disclosed above apply mutatis mutandis to the method.

Suitably, the aforementioned method is an effective and robust method for providing functional analysis of the device itself as well as components installed therein that may be concealed therein.

Optionally, the functional test analysis comprises: an identity of the device, indication of functionality pass or failure of the device, nature of failure of the device, threshold of pass or failure for the device, component missing or mismatch in the device.

Optionally, the one or more states of the device is selected from: a charging status or a working mode of the device or other user interface function.

Optionally, the encoded signal is generated in accordance with an encoding scheme.

Optionally, the encoding scheme is selected from at least one of: a Manchester line coding, a return to zero (RZ) line coding, a non return to zero (NRZ) line coding.

Optionally, the encoded signal is implemented as a lighting pattern corresponding to electrical signals of a single wire serial interface.

Optionally, the method further comprises storing the test data and the functional test analysis.

Throughout the description and claims of this specification, the words “comprise” and “contain” and variations of the words, for example “comprising” and “comprises”, mean “including but not limited to”, and do not exclude other components, integers or steps. Moreover, the singular encompasses the plural unless the context otherwise requires: in particular, where the indefinite article is used, the specification is to be understood as contemplating plurality as well as singularity, unless the context requires otherwise.

Preferred features of each aspect of the invention may be as described in connection with any of the other aspects. Within the scope of this application, it is expressly intended that the various aspects, embodiments, examples and alternatives set out in the preceding paragraphs, in the claims and/or in the following description and drawings, and in particular the individual features thereof, may be taken independently or in any combination. That is, all embodiments and/or features of any embodiment can be combined in any way and/or combination, unless such features are incompatible.

### BRIEF DESCRIPTION OF THE DRAWINGS

One or more embodiments of the invention will now be described, by way of example only, with reference to the accompanying drawings, in which:

FIG. 1 is a block diagram of a system for performing functional testing of a device on a production line, in accordance with an embodiment of the present disclosure;

FIG. 2 is a schematic illustration of an encoded signal generated in accordance with an encoding scheme; and

FIG. 3 is a flowchart depicting steps of a method for performing functional testing of a device on a production line, in accordance with an embodiment of the present disclosure.

### DETAILED DESCRIPTION OF THE DRAWINGS

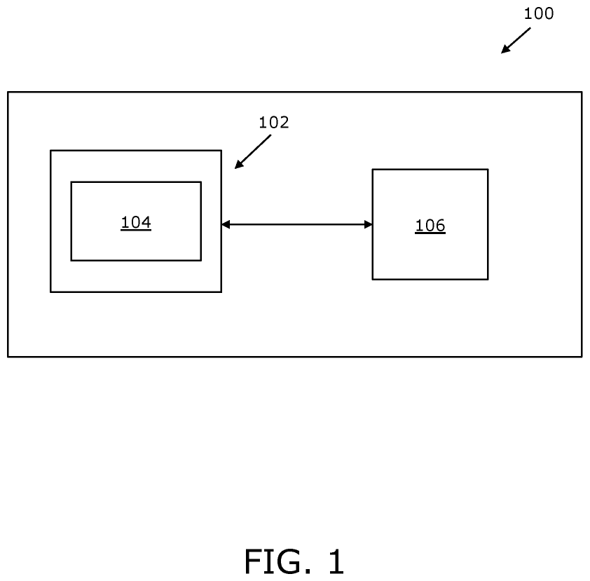

Referring to FIG. 1, illustrated is a block diagram of a system 100 for performing functional testing of a device 102 on a production line, in accordance with an embodiment of the present disclosure. Herein, the system 100 comprises a self-testing protocol 104 configured to conduct a functionality test on a plurality of components in the device 102 and generate test data that corresponds to a result of the functionality test. Moreover, the device 102 comprises one or more Light Emitting Diodes or other light emitting means 106 configured to generate an encoded signal corresponding to the generated test data, and provide a user interface for indicating one or more states of the device to an end user. Furthermore, the system 100 comprises a reader 108 configured to read and decode the encoded signal to provide a functional test analysis for the device 102.

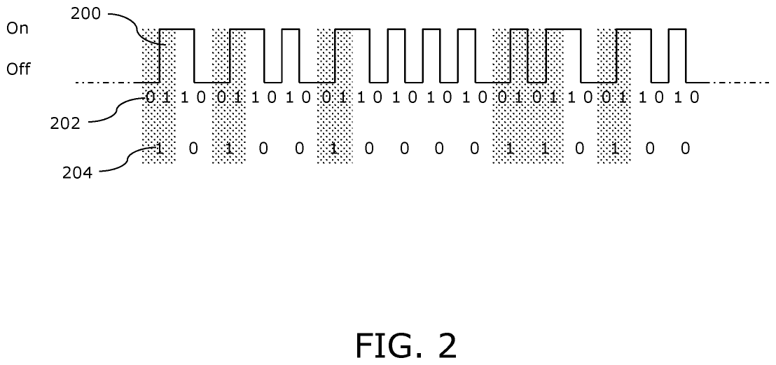

Referring to FIG. 2, illustrated is a schematic illustration of an encoded signal 200 generated in accordance with an encoding scheme 202. As shown, the encoding scheme 202 is a Manchester line coding for representing bits of a test data 204 as a digital serial signal. Moreover, based on the bits of a test data 204, the encoded signal 200 is generated using one or more LED's. Herein, the Manchester line coding allows for the brightness of the LED's, during transmission, to be constant apparent illumination that is independent of the data being sent. In other words, the data rate that is used is faster than is perceived by the human eye.

Therefore, the test information can be communicated using the same set of LED(s) that is also used for providing visual indications to an end user of the device. Advantageously, this saves cost and space as no extra hardware is needed in the device to implement this feature.

Notably, encoding of the test data 204 is a way of representing binary bits of the test data 204 used by the one or more LED's to generate the corresponding encoded signal 200, and decoding of the encoded signal 202 is a way of retrieving the original bits of the test data 204 that are encoded according to the encoding scheme 202.

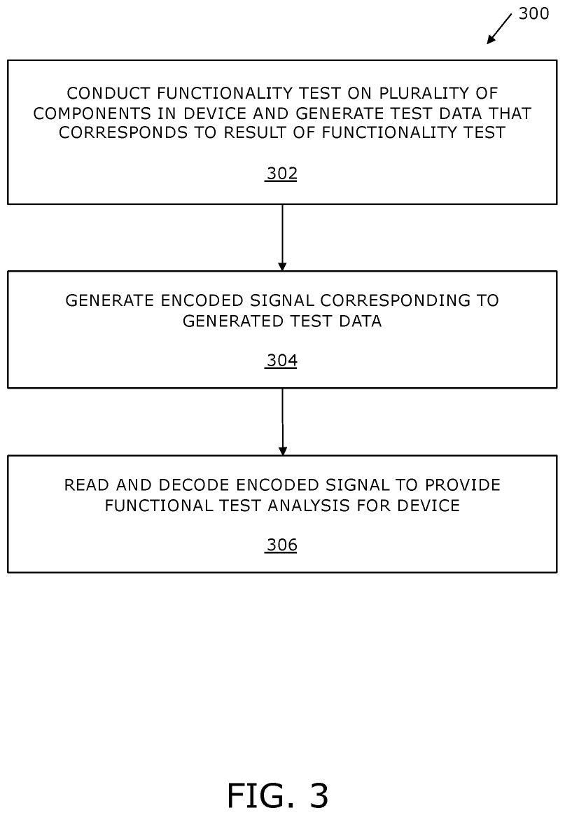

Referring to FIG. 3, illustrated is a flowchart 300 of a method for performing functional testing of a device on a production line, in accordance with an embodiment of the present disclosure. At step 302, a functionality test is conducted on a plurality of components in the device and a test data that corresponds to a result of the functionality test is generated. At step 304, an encoded signal corresponding to the generated test data is generated. At step 306, one or more states of the device is indicated, via a user interface, to an end user At step 308, the encoded signal is read and decoded to provide a functional test analysis for the device.

The steps 302, 304, 306 and 308 are only illustrative and other alternatives can also be provided where one or more steps are added, one or more steps are removed, or one or more steps are provided in a different sequence without departing from the scope of the claims herein.

In view of the foregoing, in the present invention, use of a specific encoding scheme, such as Manchester coding, enables the self test/diagnostic information to co-exist and be transmitted with no noticeable change to the end user. Due to the high speed of encoding, the self-test/diagnostic information is not visible to the end user. Therefore, the same set of LEDs can perform their usual function of providing a visual indication to the end user (e.g., indicating charging status, mode of operation, or any other user action). The LEDs would appear in a constant state to the user, even though they are actually blinking at a very fast rate and encoding the self-test/diagnostic information. Advantageous, this saves both cost and space as no extra hardware is required to enable such testing/diagnostic functionality on the production line.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural.

1. A system for performing functional testing of a device on a production line, wherein the system comprising:
a self-testing protocol configured to conduct a functionality test on a plurality of components in the device and generate a test data that corresponds to a result of the functionality test;
one or more Light Emitting Diodes or other light emitting means configured to
generate an encoded signal corresponding to the generated test data, and
provide a user interface for indicating one or more states of the device to an end user; and
a reader configured to read and decode the encoded signal to provide a functional test analysis for the device.

2. The system according to claim 1, wherein the functional test analysis comprises: an identity of the device, indication of functionality pass or failure of the device, nature of failure of the device, threshold of pass or failure for the device, component missing or mismatch in the device.

3. The system according to claim 1, wherein the one or more Light Emitting Diodes or other light emitting means, selected from at least one of: Organic Light Emitting Diodes, Light Emitting Polymers, Electro-Luminescent Panels, Laser Diodes, Quantum Dot Displays, Incandescent Lamps and Fluorescent Lamps, are configured to indicate the one or more states of the device selected from: a charging status or a working mode of the device or other user interface function

4. The system according to claim 1, wherein the encoded signal is generated in accordance with an encoding scheme.

5. The system according to claim 4, wherein the encoding scheme is selected from at least one of: a Manchester line coding, a return to zero (RZ) line coding, a non return to zero (NRZ) line coding.

6. The system according to claim 5, wherein the encoded signal is implemented as a lighting pattern corresponding to electrical signals of a single wire serial interface.

7. The system according to claim 1, further comprising a storage database configured to store the test data and the functionality test analysis.

8. A method for performing functional testing of a device on a production line, wherein the method comprising:
conducting a functionality test on a plurality of components in the device and generating a test data that corresponds to a result of the functionality test;
generating at least one of: an encoded signal corresponding to the generated test data, and optionally, indicating one or more states of the device to an end user; and
reading and decoding the encoded signal to provide a functional test analysis for the device.

9. The method according to claim 8, wherein the functional test analysis comprises: an identity of the device, indication of functionality pass or failure of the device, nature of failure of the device, threshold of pass or failure for the device, component missing or mismatch in the device.

10. The method according to claim 8, wherein the one or more states of the device is selected from: a charging status or a working mode of the device or other user interface function.

11. The method according to claim 8, wherein the encoded signal is generated in accordance with an encoding scheme.

12. The method according to claim 11, wherein the encoding scheme is selected from at least one of: a Manchester line coding, a return to zero (RZ) line coding, a non return to zero (NRZ) line coding.

13. The method according to claim 12, wherein the encoded signal is implemented as a lighting pattern corresponding to electrical signals of a single wire serial interface.

14. The method according to claim 8, further comprising storing the test data and the functional test analysis.
